(19) United States
(12) Patent Application Publication
(10) Pub. No.: US 2015/0351282 A1
(43) Pub. Date: Dec. 3, 2015

(54) ELECTRONIC DEVICE AND DISPLAY DEVICE

(71) Applicant: KABUSHIKI KAISHA TOSHIBA, Tokyo (JP)

(72) Inventor: Nobuto FUJIWARA, Hamura Tokyo (JP)

(21) Appl. No.: 14/822,784

(22) Filed: Aug. 10, 2015

Related U.S. Application Data
(63) Continuation of application No. PCT/JP2013/059570, filed on Mar. 29, 2013.

(51) Int. Cl. H05K 7/20; H05K 5/00

(52) U.S. Cl. CPC H05K 7/20336; H05K 7/20136; H05K 7/2039; H05K 5/0017

(57) ABSTRACT

According to one embodiment, an electronic device includes a housing, a heat-producing element inside the housing, a heat pipe contacting the housing between the housing and the heat-producing element while one end of the heat pipe is disposed in the proximity of the heat-producing element, and a heat-radiating element contacting the other end of the heat pipe to absorb heat from the heat pipe.

### CROSS-REFERENCE TO RELATED APPLICATIONS

This application is a Continuation application of PCT Application No. PCT/JP2013/059570, filed Mar. 29, 2013, the entire contents of which are incorporated herein by reference.

### FIELD

Embodiments described herein relate generally to an electronic device with a heat pipe and a display device with a heat pipe.

### BACKGROUND

Electronic devices include circuit components such as a CPU which are packed at high density into their housings. The circuit components are highly integrated and perform high-speed data processing, and consequently produce a large amount of heat. Therefore, a method for managing the heat radiated by the circuit components has great technical importance.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary front view showing a television of a first embodiment;

FIG. 2 is an exemplary cross-sectional view taken along line F2-F2 in FIG. 1;

FIG. 3 is an exemplary perspective view showing a portable computer of a second embodiment;

FIG. 4 is an exemplary cross-sectional view taken along line F4-F4 in FIG. 3;

FIG. 5 is an exemplary cross-sectional view showing a portable computer of a third embodiment, focusing on a heat pipe and its periphery;

FIG. 6 is an exemplary cross-sectional view showing a portable computer of a fourth embodiment, focusing on a heat pipe and its periphery;

FIG. 7 is an exemplary perspective view showing a portable computer of a fifth embodiment, focusing on a first heat pipe and a second heat pipe and their periphery;

FIG. 8 is an exemplary cross-sectional view showing a portable computer of a sixth embodiment, focusing on a first heat pipe and a second heat pipe and their periphery;

FIG. 9 is an exemplary cross-sectional view showing a portable computer of a seventh embodiment, focusing on a first heat pipe and a second heat pipe and their periphery; and

FIG. 10 is an exemplary cross-sectional view showing a portable computer of an eighth embodiment, focusing on a heat pipe and its periphery.

### DETAILED DESCRIPTION

Various embodiments will be described hereinafter with reference to the accompanying drawings.

In general, according to one embodiment, an electronic device comprises a housing, a heat-producing element inside the housing, a heat pipe contacting the housing between the housing and the heat-producing element while an end of the heat pipe is disposed in the proximity of the heat-producing element, and a heat-radiating element contacting the other end of the heat pipe to absorb heat from the heat pipe.

### First Embodiment

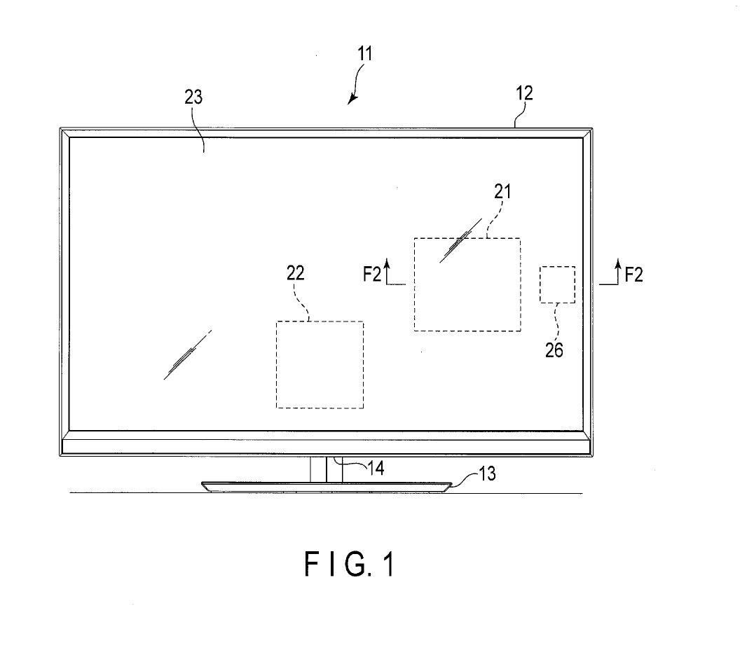

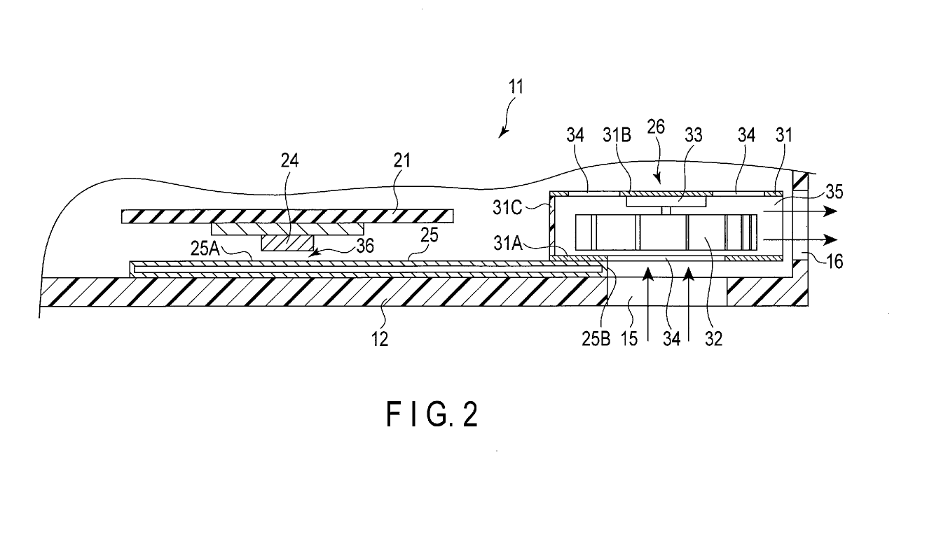

Hereinafter, a first embodiment is described with reference to FIGS. 1 and 2. FIG. 1 shows a television 11 which is an example of the display device of the first embodiment. The television 11 has a substantially rectangular (square or flat box-shape) exterior. The display device is not limited to the television 11, and may be a variety of display devices which display images, such as, a television receiver, a broadcast receiver, a receiver, or an image display apparatus.

As in FIGS. 1 and 2, the television 11 comprises a housing 12 formed of, for example, a synthetic resin material and a support 13 which supports the housing 12. The support 13 includes a swivel 14 used to turn the housing 12 horizontally. The housing 12 includes an intake 15 to take in air and an exhaust 16 to discharge exhaust from a fan unit 26 while the intake 15 and the exhaust 16 are disposed to correspond to the position of the fan unit 26.

The television 11 includes, inside the housing 12, a system substrate 21 (printed circuit board or circuit substrate) configured to control the components of the television 11 collectively, power circuit board 22 (power source, power source unit, or power source controller), and flat plate-like display panel 23 including a display surface to display images. The system substrate 21 includes, for example, a tuner.

The display panel 23 is, for example, a liquid crystal display panel. Or, various kinds of display panels can be adopted for the display panel 23 such as a plasma display panel, organic electroluminescent (EL) panel, plastic display panel, and sheet display panel.

As shown in FIG. 2, the television 11 further comprises a heat-producing element 24 provided with the system substrate 21, heat pipe 25 provided with the inner surface of the housing 12, and fan unit 26 which takes the heat from the heat pipe 25. The heat pipe 25 can be interpreted as a rod-shaped thermal transmissible element.

The heat-producing element 24 is provided in the proximity of the housing 12. The heat-producing element 24 is, for example, a graphics chip; however, it is not limited to a graphics chip and may be any other exothermic element such as CPU, memory, chip set, LED chip as a light source, wireless communication unit, and power source component.

The fan unit 26 is an example of heat-radiating element. The fan unit 26 includes a fan case 31, impeller 32 rotatably accommodated within the fan case 31, and motor 33 which rotates the impeller 32. The fan case 31 has a first wall 31A and a second wall 31B which are formed of a metal and a third wall 31C which is formed of a synthetic resin. The first and second walls 31A and 31B are formed of a metal material having excellent thermal transmissivity such as aluminum alloy and formed in a plate-like shape. Each of the first and second walls 31A and 31B has an inlet port 34. The third wall 31C forms a peripheral wall of the fan case 31 and has an outlet port 35 in its part.

The heat pipe 25 is adhered to the inner surface of the housing 12 with, for example, double-sided tape to be provided integrally with the housing 12. The fixing of the heat pipe 25 to the housing 12 is not limited to adhesion, and the heat pipe 25 may originally be formed integrally with the housing 12 through an insert formation. The heat pipe 25 is formed in a flat rod-like shape through its entirety. The heat pipe 25 is, for example, composed of a hollow plate-like shape container formed of a copper material and a working fluid such as water sealed inside the container.

The heat pipe 25 includes an end 25A provided in the proximity of the heat-producing element 24 and the other end 25B thermally connected to the first wall 31A of the fan case 31. In the heat pipe 25, the working fluid is evaporated while taking ambient heat at the end 25A side, and the vaporized fluid is conveyed to the other end 25B side. The working fluid is condensed at the other end 25B side to release heat to the periphery.

The heat pipe 25 is, as compared to a heat pipe having a circular cross-section, formed thinner. The thickness dimension of the heat pipe 25 is, for example, 0.5 to 1.0 mm.

The end 25A of the heat pipe 25 is positioned in a gap 36 between a part of the wall of the housing 12 and the heat-producing element 24. The height of the gap 36 is set to approximately 1.0 to 2.0 mm which is large enough to accommodate the end 25A of the heat pipe 25 therein.

The other end 25B of the heat pipe 25 contacts the first wall 31A of the fan case 31. Between the end 25B and the first wall 31A, a sheet (cooling sheet or adhesive sheet) having good thermal transmissivity and double-sided adherence is interposed, for example. The sheet is formed of, for example, a resin material. The end 25B and the first wall 31A may be adhered to each other by, for example, brazing without such a sheet interposed therebetween. In the present embodiment, the heat pipe 25 is closely adhered to the wall at the rear side of the housing 12.

Now, a cooling effect in the television 11 of the first embodiment will be explained with reference to FIG. 2. When the television 11 is used, the heat-producing element 24 produces heat which is transmitted to a part of the housing 12 in the proximity thereof through ambient air. The heat transmitted to the part of the housing 12 is transmitted to the end 25A of the heat pipe 25. The heat transmitted to the end 25A is transmitted to the other end 25B of the heat pipe 25 through the working fluid. The heat released from the end 25B is transmitted to the first wall 31A of the fan case 31.

In the fan case 31, the heat transmitted to the first wall 31A is absorbed by fresh air taken in by the intake 15 of the housing 12 and passing through the inlet port 34. Similarly, the heat of the first wall 31A is absorbed by air flowing inside the fan case 31. Thus, the heat transmitted to the first wall 31A is transmitted to the air inside the fan case 31 and is released outside the housing 12 through the exhaust 16.

In the first embodiment, the television 11 comprises the housing 12, the heat-producing element 24 accommodated within the housing 12, the heat pipe 25 contacting the housing 12 between the housing 12 and the heat-producing element 24 while the end 25A of the heat pipe 25 is disposed in the proximity of the heat-producing element 24, and the fan unit 26 contacting the other end 25B of the heat pipe 25 to absorb the heat from the heat pipe 25.

If the heat-producing element 24 is disposed near the housing 12, the heat irradiated from the heat-producing element 24 may concentrate at a certain part of the housing 12 and the part may be extremely hot. Since the heat from the heat-producing element 24 to the housing 12 is diffused from the end 25B of the heat pipe 25 to the fan case 31 of the fan unit 26, the heat can be released outside the housing 12 by the fan unit 26. Therefore, local concentration of heat from the heat-producing element 24 in the housing 12 can be prevented.

The fan unit 26 has the fan case 31 including the first and second metal walls 31A and 31B, and the end 25B of the heat pipe 25 is thermally connected to the first wall 31A. The fan case 31 of the fan unit 26 is sufficiently cooled by an air flow produced by the impeller 32. With this structure, the heat transmitted to the end 25B of the heat pipe 25 can efficiently be transmitted to the air flow contacting onto the first wall 31A of the fan case 31.

The first wall 31A has the inlet port 34 to take the air outside the housing 12 in the fan case 31. With this structure, the end 25B of the heat pipe 25 can be thermally connected to the first wall 31A at the side to take in air outside the housing 12, that is, fresh air. Thus, the housing 12 in the proximity of the heat-producing element 24 and the heat pipe 25 connected thereto can be cooled more efficiently.

### Second Embodiment

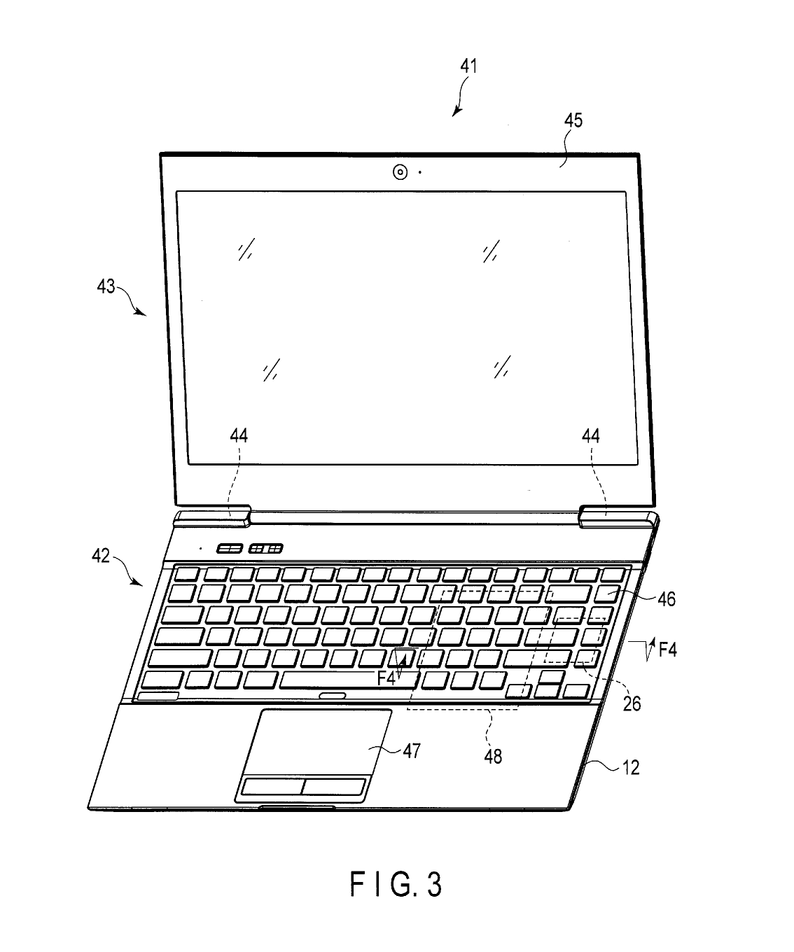

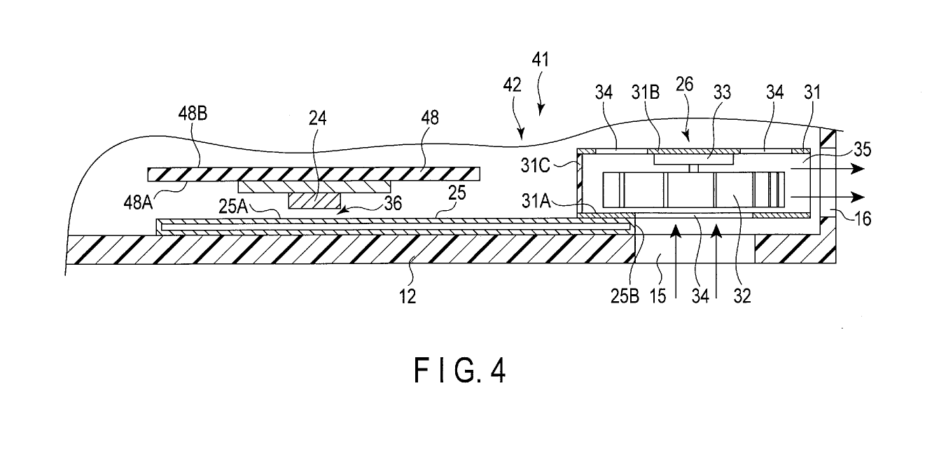

Now, a second embodiment is described with reference to FIGS. 3 and 4. In the second embodiment, a portable computer 41 which is an example of the electronic device is described. Although the exterior of the portable computer 41 is different from that of the television 11 of the first embodiment, some of the internal structures are shared therebetween. Therefore, only the structures different are explained and the same structures will be referred to by the reference numbers used in the aforementioned embodiment while their explanation is omitted.

As shown in FIG. 3, the portable computer 41 comprises a main body 42, a display 43, and a pair of hinges 44 provided between the main body 42 and the display 43. The hinges 44 support the display 43 to the main body 42 in a rotatable manner.

The display 43 includes a display panel 23 and a display case 45 surrounding the display panel 23. The display case 45 is formed of, for example, a synthetic resin material. The display panel 23 is, in the present embodiment, a liquid crystal display panel. Or, various kinds of display panels can be adopted for the display panel 23 such as a plasma display panel, organic EL panel, plastic display panel, and sheet display panel.

As shown in FIGS. 3 and 4, the main body 42 comprises a housing 12 formed of, for example, a synthetic resin material in a box-like shape, keyboard 46 disposed on the upper surface of the housing 12, touch pad 47 disposed on the upper surface of the housing 12, printed circuit board 48 accommodated within the housing 12, and heat-producing element 24 disposed on the printed circuit board 48.

As shown in FIG. 4, the printed circuit board 48 has a first surface 48A with which a heat-producing element 24 is provided and a second surface 48B opposed to the first surface 48A. The first surface 48A faces the bottom wall of the housing 12.

A CPU which is not shown is provided with the printed circuit board 48. The heat-producing element 24 is, for example, a graphics chip; however, it is not limited to a graphics chip and may be any other exothermic element such as CPU, memory, chip set, LED chip as a light source, wireless communication unit, and power source component.

As shown in FIG. 4, the main body 42 further comprises a heat pipe 25 disposed on the inner surface of the housing 12, and a fan unit 26 which takes the heat from the heat pipe 25.

The fan unit 26 and the heat pipe 25 are structured the same as in the first embodiment. The fan unit 26 is an example of the heat-radiating element thermally connected to an end 25B of the hear pipe 25. In the present embodiment, the heat pipe 25 is adhered to the bottom wall of the housing 12 by a double-sided tape or the like to be provided integrally with the housing 12.

The end 25B of the heat pipe 25 is thermally connected to a first wall 31A of a fan case 31. Between the end 25B and the first wall 31A, a sheet (cooling sheet or adhesive sheet) having good thermal transmissivity and double-sided adherence is interposed, for example. The sheet is formed of, for example, a resin material. The end 25B and the first wall 31A may be adhered to each other by, for example, brazing without such a sheet interposed therebetween.

Now, a cooling effect in the portable computer 41 of the present embodiment will be explained with reference to FIG. 4. When the portable computer 41 is used, the heat-producing element 24 produces heat which is transmitted to a part of the housing 12 in the proximity thereof through ambient air. The heat transmitted to the part of the housing 12 is transmitted to an end 25A of the heat pipe 25 and is further transmitted to the other end 25B of the heat pipe 25 through a working fluid. The heat released from the end 25B is transmitted to the first wall 31A of the fan case 31.

In the fan case 31, the heat transmitted to the first wall 31A is absorbed by fresh air taken in by an intake 15 of the housing 12 and passing through an inlet port 34. Similarly, the heat of the first wall 31A is absorbed by air flowing inside the fan case 31. Thus, the heat from the heat-producing element 24 transmitted to the first wall 31A is transmitted to the air inside the fan case 31 and is released outside the housing 12 from an exhaust 16.

In the second embodiment, the heat from the heat-producing element 24 to the housing 12 can be diffused to the fan case 31 of the fan unit 26 from the end 25B of the heat pipe 25 and released outside the housing 12 by the fan unit 26. Therefore, local concentration of heat in the housing 12 can be prevented.

### Third Embodiment

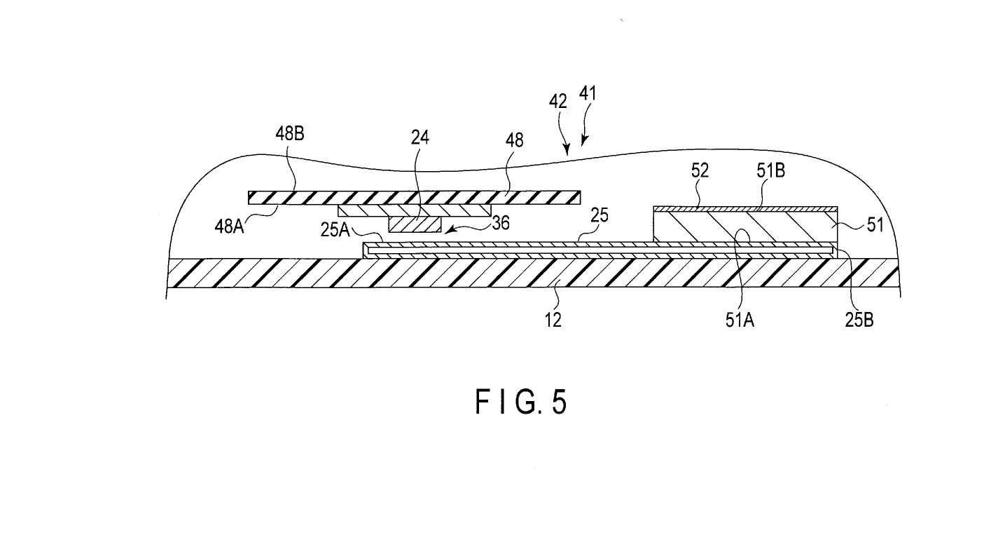

Now, a third embodiment is explained with reference to FIG. 5. A portable computer 41 which is an example of the electronic device of the third embodiment is basically the same as that of the second embodiment except that a Peltier device 51 is used instead of a fan unit 26 in the portable computer 41. Therefore, only the structures different are explained and the same structures will be referred to by the reference numbers used in the aforementioned embodiment while their explanation is omitted. The portable computer 41 of the third embodiment has the same exterior of that of the portable computer 41 of the second embodiment in FIG. 3.

A main body 42 comprises a heat pipe 25 disposed on the inner surface of a housing 12, Peltier device 51 which takes heat from the heat pipe 25, and heat-radiating plate 52 disposed to contact a heat releasing surface 51B of the Peltier device 51.

The heat pipe 25 is structured the same as that of the first embodiment. The Peltier device 51 is an example of the heat-radiating element.

The Peltier device 51 has a heat-absorbing surface 51A disposed to contact an end 25B of the heat pipe 25 and the heat releasing surface 51B disposed to be opposed to the heat-absorbing surface 51A. The Peltier device 51 is thermally connected to the heat pipe 25 through the heat-absorbing surface 51A. The Peltier device 51 is thermally connected to the heat-radiating plate 52 through the heat releasing surface 51B.

Between the end 25B of the heat pipe 25 and the heat-absorbing surface 51A, a sheet (cooling sheet or adhesive sheet) having good thermal transmissivity and double-sided adherence is interposed, for example. The sheet is formed of, for example, a resin material. The end 25B and the heat-absorbing surface 51A may be adhered to each other by, for example, brazing without such a sheet interposed therebetween.

Now, a cooling effect in the portable computer 41 of the present embodiment will be explained with reference to FIG. 5. When the portable computer 41 is used, the heat-producing element 24 produces heat which is transmitted to a part of the housing 12 in the proximity thereof through ambient air. The heat transmitted to the part of the housing 12 is transmitted to an end 25A of the heat pipe 25 and is further transmitted to the other end 25B of the heat pipe 25 through a working fluid. The heat released from the end 25B is transmitted to the heat-absorbing surface 51A of the Peltier device 51. The Peltier device 51 actively transmits the heat of the heat-absorbing surface 51A toward the heat releasing surface 51B. The heat transmitted to the heat releasing surface 51B is released to the air through the heat-radiating plate 52.

In the third embodiment, the heat from the heat-producing element 24 to the housing 12 can be transmitted to the Peltier device 51 from the end 25B of the heat pipe 25 and the heat can be released outside through the Peltier device 51. Therefore, local concentration of heat in the housing 12 can be prevented.

### Fourth Embodiment

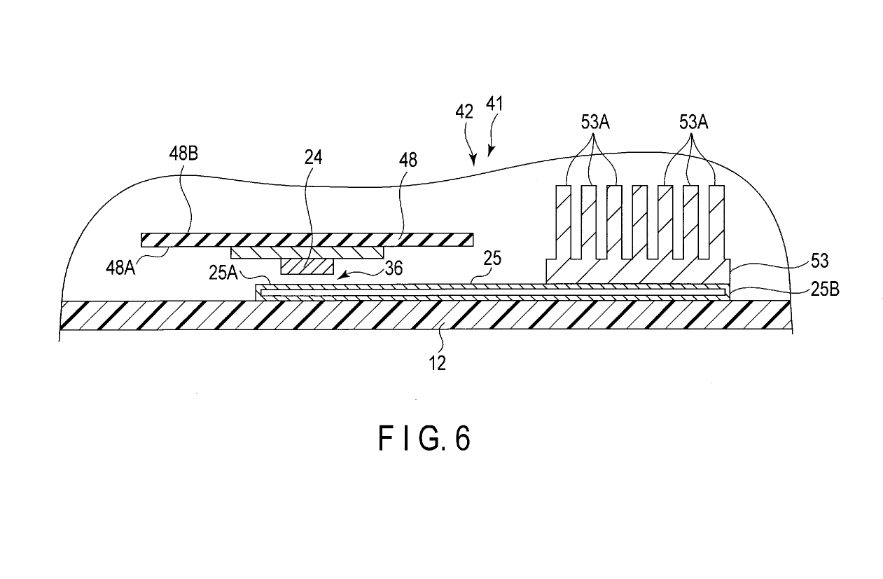

Now, a fourth embodiment is explained with reference to FIG. 6. A portable computer 41 which is an example of the electronic device of the fourth embodiment is basically the same as that of the second embodiment except that a heat sink 53 is used instead of a fan unit 26 in the portable computer 41. Therefore, only the structures different are explained and the same structures will be referred to by the reference numbers used in the aforementioned embodiment while their explanation is omitted. The portable computer 41 of the fourth embodiment has the same exterior as that of the portable computer 41 of the second embodiment in FIG. 3.

As shown in FIG. 6, a main body 42 comprises a heat pipe 25 disposed on the inner surface of a housing 12 and a heat sink 53 which takes heat from the heat pipe 25.

The heat pipe 25 is structured the same as that of the first embodiment. The heat sink 53 is an example of the heat-radiating element.

The heat sink 53 includes a plurality of heat releasing fins 53A and they are formed integrally of an aluminum alloy, for example. The heat sink 53 is thermally connected to an end 25B of the heat pipe 25.

Between the end 25B of the heat pipe 25 and the heat sink 53, a sheet (cooling sheet or adhesive sheet) having good thermal transmissivity and double-sided adherence is interposed, for example. The sheet is formed of, for example, a resin material. The end 25B and the heat sink 53 may be adhered to each other by, for example, brazing without such a sheet interposed therebetween.

Now, a cooling effect in the portable computer 41 of the present embodiment will be explained with reference to FIG. 6. When the portable computer 41 is used, the heat-producing element 24 produces heat which is transmitted to a part of the housing 12 in the proximity thereof through ambient air. The heat transmitted to the part of the housing 12 is transmitted to an end 25A of the heat pipe 25 and is further transmitted to the other end 25B of the heat pipe 25 through a working fluid. The heat released from the end 25B is transmitted to the heat sink 53. The heat transmitted to the heat sink 53 is released to the air through the fins 53A.

In the fourth embodiment, the heat from the heat-producing element 24 to the housing 12 can be diffused to the heat sink 53 from the end 25B of the heat pipe 25 and released outside by the heat sink 53. Therefore, local concentration of heat in the housing 12 can be prevented.

### Fifth Embodiment

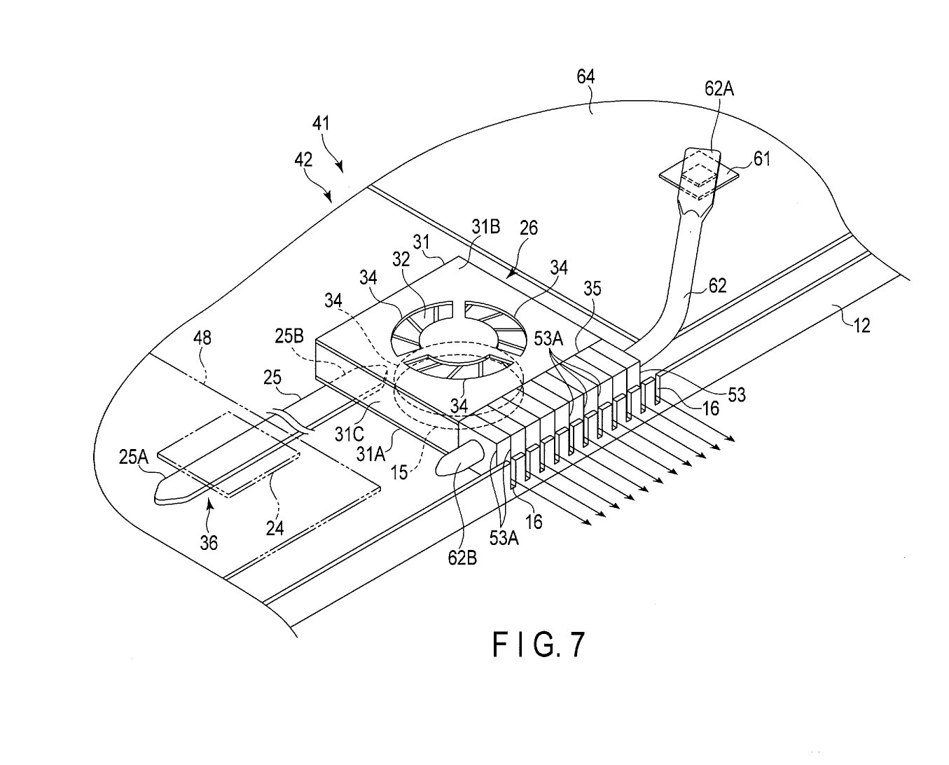

Now, a fifth embodiment is explained with reference to FIG. 7. A portable computer 41 which is an example of the electronic device of the fifth embodiment is basically the same as that of the second embodiment except that the portable computer 41 further includes a second heat-producing element 61 and a second heat pipe 62. Therefore, only the structures different are explained and the same structures will be referred to by the reference numbers used in the aforementioned embodiment while their explanation is omitted. The portable computer 41 of the fifth embodiment has the same exterior as that of the portable computer 41 of the second embodiment in FIG. 3.

FIG. 7 shows the lower half of the housing 12 while the upper half of the housing 12 is omitted.

The main body 42 comprises a first printed circuit board 48, heat-producing element 24 provided with the first printed circuit board 48, first heat pipe 25 disposed on the inner surface of the housing 12, fan unit 26 which takes heat from the first heat pipe 25, second printed circuit board 64, second heat-producing element 61 provided with the second printed circuit board 64, second heat pipe 62, and heat sink 53 thermally connected to the second heat pipe 62. The first heat pipe 25 is structured the same as that of the second embodiment.

The heat-producing element 24 is, for example, a graphics chip; however, it is not limited to a graphics chip and may be any other exothermic element such as CPU, memory, chip set, LED chip as a light source, wireless communication unit, and power source component.

The second heat-producing element 61 is, for example, a CPU; however, it is not limited to a CPU and may be any other exothermic element such as graphics chip, memory, chip set, LED chip as a light source, wireless communication unit, and power source component.

The second heat pipe 62 is formed in a slender rod-like shape with a cylindrical cross-section. The second heat pipe 62 is, for example, composed of a hollow plate-like shape container formed of a copper material and a working fluid such as water sealed inside the container. The second heat pipe 62 has a first end 62A thermally connected to the second heat-producing element 61 and a second end 62B disposed in the proximity of the fan unit 26.

In the second heat pipe 62, the working fluid is evaporated while taking ambient heat at the first end 62A side, and the vaporized fluid is conveyed to and condensed at the second end 62B side to release the heat to the periphery. A heat sink 53 is fixed to the second end 62B. The heat sink 53 includes a plurality of fins 53A arranged linearly. The fins 53A of the heat sink 53 are arranged between an outlet port 35 of the fan case 31 and exhaust 16 of the housing 12.

Now, a cooling effect in the portable computer 41 of the present embodiment will be explained with reference to FIG. 7. When the portable computer 41 is used, the heat-producing element 24 produces heat which is transmitted to a part of the housing 12 in the proximity thereof through ambient air. The heat transmitted to the part of the housing 12 is transmitted to an end 25A of the first heat pipe 25 and is further transmitted to the other end 25B of the heat pipe 25 through a working fluid. The heat released from the end 25B is transmitted to the first wall 31A of the fan case 31.

In the fan case 31, the heat transmitted to the first wall 31A is constantly absorbed by air outside the housing 12 taken in by an intake 15 and passing through an inlet port 34 and by air flowing inside the fan case 31. Thus, the heat from the heat-producing element 24 to the first wall 31A is released outside the housing 12 with the air flow.

Similarly, when the portable computer 41 is used, the second heat-producing element 61 produces heat. The heat from the second heat-producing element 61 is transmitted to the first end 62A of the second heat pipe 62 and is conveyed to the other end 62B of the second heat pipe 62 through the working fluid to be transmitted to the heat sink 53. The heat sink 53 is cooled by the air from the fan unit 26 to the outside of the housing 12 through an exhaust 16. Thereby, the heat from the second heat-producing element 61 to the heat sink 53 is released outside the housing 12.

In the fifth embodiment, the portable computer 41 comprises a second heat-producing element 61 accommodated within the housing 12, and a second heat pipe 62 including a first end 62A thermally connected to the second heat-producing element 61 and a second end 62B disposed in the proximity of the fan unit 26 to be cooled thereby.

With the structure described above, a single fan unit 26 for cooling the second heat pipe 62 can be used for cooling of the first heat pipe 25. Therefore, the number of fan units can be reduced and the portable computer 41 can be miniaturized.

### Sixth Embodiment

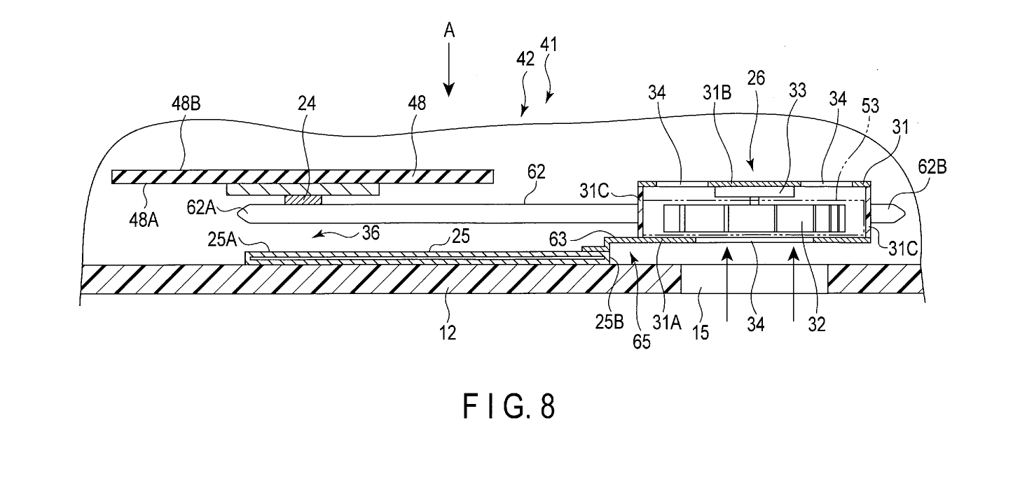

Now, a sixth embodiment is explained with reference to FIG. 8. A portable computer 41 which is an example of the electronic device of the sixth embodiment is basically the same as that of the second embodiment except that the portable computer 41 further includes a second heat pipe 62 for directly cooling of a heat-producing element 24 and a leg 63 disposed between an end 25B of a first heat pipe 25 and a fan unit 26. Therefore, only the structures different are explained and the same structures will be referred to by the reference numbers used in the aforementioned embodiment while their explanation is omitted. The portable computer 41 of the sixth embodiment has the same exterior as that of the portable computer 41 of the second embodiment in FIG. 3.

As shown in FIG. 8, a main body 42 comprises a first printed circuit board 48, heat-producing element 24 provided with the first printed circuit board 48, first heat pipe 25 disposed on the inner surface of the housing 12, fan unit 26 which takes heat from the first heat pipe 25, second heat pipe 62, heat sink 53 thermally connected to the second heat pipe 62, and leg 63 disposed in a second gap 65 between an end 25B of the first heat pipe 25 and a first wall 31A of the fan unit 26.

The heat-producing element 24 is, for example, a graphics chip; however, it is not limited to a graphics chip and may be any other exothermic element such as a CPU, memory, chip set, LED chip as a light source, wireless communication unit, and power source component.

The first heat pipe 25 is structured the same as that of the second embodiment.

The second heat pipe 62 is formed in a slender rod-like shape with a cylindrical cross-section. The second heat pipe 62 has a first end 62A thermally connected to the heat-producing element 24 and a second end 62B disposed in the proximity of the fan unit 26. In the second heat pipe 62, a working fluid is evaporated while taking ambient heat at the first end 62A side, and the vaporized fluid is conveyed to and condensed at the second end 62B side to release the heat to the periphery. The second heat pipe 62 is, as indicated by arrow A in FIG. 8, positioned to substantially overlap with the first heat pipe 25 when the housing 12 is viewed from its thickness direction.

The heat sink 53 is fixed to the second end 62B. The heat sink 53 is structured the same as that of the fifth embodiment.

The leg 63 which is an example of a connection portion thermally connects the first wall 31A of the fan case 31 to the end 25B of the first heat pipe 25. In the present embodiment, the leg 63 is formed integrally with the first wall 31A of a metal material; however, the leg 63 may be formed separately from but adhering to the first wall 31A. The leg 63 is formed to have a step in its intermediate part. The leg 63 is, for example, fixed to the end 25B of the first heat pipe 25 by brazing or the like.

Now, a cooling effect in the portable computer 41 of the present embodiment will be explained with reference to FIG. 8. When the portable computer 41 is used, the heat-producing element 24 produces heat which is transmitted to the first end 62A of the second heat pipe 62. The heat transmitted to the first end 62A is transmitted to an end 62B of the second heat pipe 62 through a working fluid and is further transmitted to the heat sink 53. The heat sink 53 is cooled by the air from the fan unit 26 to the outside of the housing 12. Thereby, the heat from the heat-producing element 24 to the heat sink 53 is released to outside the housing 12.

The heat from the heat-producing element 24 is transmitted to a part of the housing 12 in the proximity thereof through ambient air. The heat transmitted to the part of the housing 12 is transmitted to an end 25A of the first heat pipe 25. The heat transmitted to the end 25A is transmitted to the other end 25B from the end 25A by the action of the first heat pipe 25. The heat released from the end 25B is transmitted to the first wall 31A of the fan case 31 through the leg 63.

In the fan case 31, the heat transmitted to the first wall 31A is absorbed by fresh air taken in by an intake 15 of the housing 12 and passing through an inlet port 34. Similarly, the heat of the first wall 31A is absorbed by air flowing inside the fan case 31. Thus, the heat transmitted to the first wall 31A is transmitted to the air inside the fan case 31 and is released outside the housing 12 with the air flow.

In the sixth embodiment, the portable computer 41 comprises the leg 63 disposed in a second gap 65 between the end 25B of the first heat pipe 25 and the fan unit 26 to thermally connect the end 25B of the first heat pipe 25 to the first wall 31A, and a second heat pipe 62 including a first end 62A thermally connected to the heat-producing element 24 and a second end 62B disposed in the proximity of the fan unit 26 to be cooled thereby.

With the structure explained above, even if the first heat pipe 25 and the fan unit 26 are apart from each other, the leg 63 can thermally connect the first wall 31A of the fan unit 26 to the first heat pipe 25. Therefore, a part of the housing 12 in the proximity of the heat-producing element 24 and the first heat pipe 25 connected thereto can be cooled efficiently.

The second heat pipe 62 is disposed to substantially overlap with the first heat pipe 25 when the housing 12 is viewed from its thickness direction. Therefore, a space in the housing 12 can be used effectively, and the portable computer 41 can be miniaturized.

### Seventh Embodiment

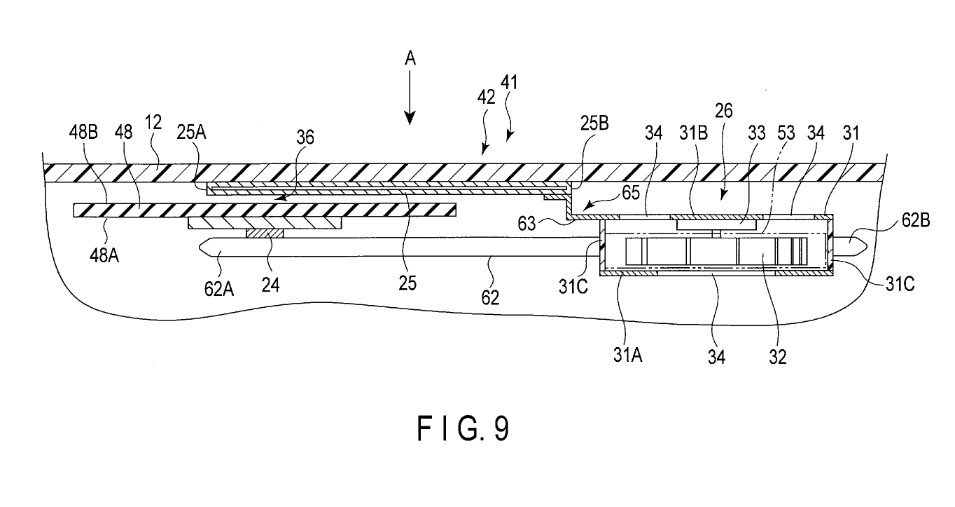

Now, a seventh embodiment is explained with reference to FIG. 9. A portable computer 41 which is an example of the electronic device of the seventh embodiment is basically the same as that of the sixth embodiment except that a first heat pipe 25 and a leg 63 are arranged in different positions. Therefore, only the structures different are explained and the same structures will be referred to by the reference numbers used in the aforementioned embodiment while their explanation is omitted. The portable computer 41 of the seventh embodiment has the same exterior as the portable computer 41 of the second embodiment in FIG. 3.

The first heat pipe 25 is structured the same as that of the sixth embodiment. However, in the present embodiment, the first heat pipe 25 is provided with the inner surface of the housing 12 to face a surface 48B of a printed circuit board 48 which is an opposite surface to a surface 48A on which a heat-producing element 24 is disposed. In other words, the heat pipe 25 is closely adhered to the inner upper surface of the housing 12.

The second heat pipe 62 is structured the same as that of the sixth embodiment. The second heat pipe 62 is, as indicated by arrow A in FIG. 9, positioned to substantially overlap with the first heat pipe 25 when the housing 12 is viewed from its thickness direction.

The leg 63 thermally connects the second wall 31B of the fan case 31 to the end 25B of the first heat pipe 25. In the present embodiment, the leg 63 is formed integrally with the first wall 31B of a metal material; however, the leg 63 may be formed separately from but adhering to the first wall 31B. The leg 63 is formed to have a step in its intermediate part. The leg 63 is, for example, fixed to the end 25B of the first heat pipe 25 by brazing or the like.

Now, a cooling effect in the portable computer 41 of the present embodiment will be explained with reference to FIG. 9. When the portable computer 41 is used, the heat-producing element 24 produces heat which is transmitted to the first end 62A of the second heat pipe 62. The heat transmitted to the first end 62A is transmitted to an end 62B of the second heat pipe 62 through a working fluid and is further transmitted to the heat sink 53. The heat sink 53 is cooled by the air from the fan unit 26 to the outside of the housing 12. Thereby, the heat from the heat-producing element 24 to the heat sink 53 is released to outside the housing 12.

The heat from the heat-producing element 24 is transmitted to a part of the housing 12 in the proximity thereof through ambient air. The heat transmitted to the part of the housing 12 is transmitted to an end 25A of the first heat pipe 25. The heat transmitted to the end 25A is transmitted to the other end 25B from the end 25A through a working fluid. The heat released from the end 25B is transmitted to the first wall 31A of the fan case 31 through the leg 63.

In the fan case 31, the heat transmitted to the second wall 31B is absorbed by air passing through an inlet port 34. Similarly, the heat of the first wall 31A is absorbed by air flowing inside the fan case 31. Thus, the heat transmitted to the second wall 31B is transmitted to the air inside the fan case 31 and is released outside the housing 12 with the air flow.

### Eighth Embodiment

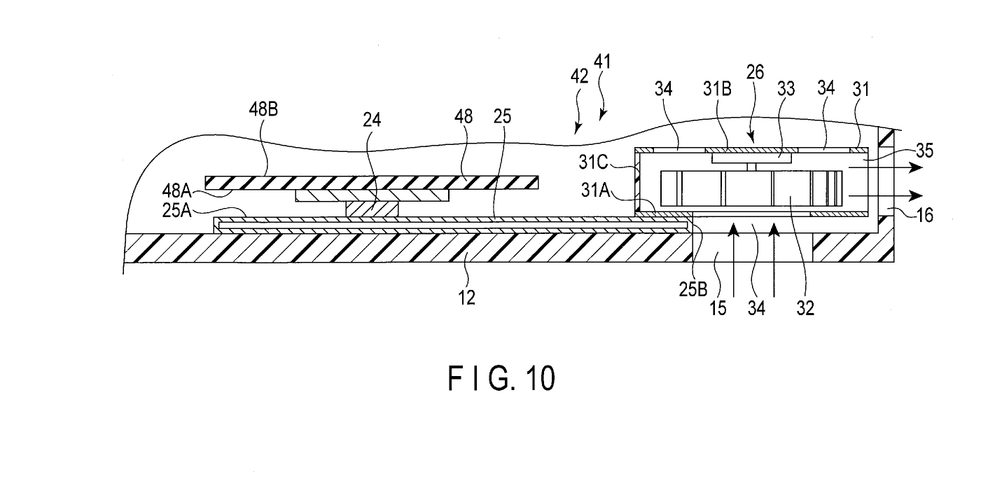

Now, an eighth embodiment is explained with reference to FIG. 10. A portable computer 41 which is an example of the electronic device of the eighth embodiment is basically the same as that of the second embodiment except that a heat-producing element 24 is thermally connected to a heat pipe 25. Therefore, only the structures different are explained and the same structures will be referred to by the reference numbers used in the aforementioned embodiment while their explanation being omitted. The portable computer 41 of the eighth embodiment has the same exterior as that of the portable computer 41 of the second embodiment in FIG. 3.

In the present embodiment, the heat-producing element 24 directly contacts an end 25A of a heat pipe 25. The heat pipe 25 is structured the same as that of the second embodiment. Between the heat-producing element 24 and the end 25A of the heat pipe 25, a sheet (cooling sheet or adhesive sheet) having good thermal transmissivity and double-sided adherence is interposed, for example. The sheet is formed of, for example, a resin material. In other words, the heat-producing element 24 is thermally connected to the end 25A of the heat pipe 25 through the sheet.

The end 25B of the heat pipe 25 contacts the first wall 31A of the fan case 31. Between the end 25B and the first wall 31A, a sheet (cooling sheet or adhesive sheet) having good thermal transmissivity and double-sided adherence is interposed, for example. The sheet is formed of, for example, a resin material. The end 25B and the first wall 31A may be adhered to each other by, for example, brazing without such a sheet interposed therebetween.

Now, a cooling effect in the portable computer 41 of the present embodiment will be explained with reference to FIG. 10. When the portable computer 41 is used, the heat-producing element 24 produces heat which is transmitted to the end 25A of the heat pipe 25. The heat transmitted to the end 25A of the heat pipe 25 is transmitted to the end 25B of the heat pipe 25 through a working fluid. The heat released from the end 25B is transmitted to the first wall 31A of the fan case 31.

In the fan case 31, the heat transmitted to the first wall 31A is absorbed by air taken in by an intake 15 of the housing 12 and passing through an inlet port 34. Similarly, the heat of the first wall 31A is absorbed by air flowing inside the fan case 31. Thus, the heat transmitted to the first wall 31A is transmitted to the air inside the fan case 31 and is released outside the housing 12 with the air flow.

With the structure of the eighth embodiment, not only the housing 12 in the proximity of the heat-producing element 24 is cooled but also the heat from the heat-producing element 24 is transmitted to the fan unit 26 using the heat pipe 25. Thus, the heat-producing element 24 itself can be cooled effectively.

The electronic device is not limited to the television 11 or the portable computer 41 described above and can be realized as other electronic devices such as mobile phone. Accordingly, various modifications may be applied to the electronic device without departing from the spirit or scope of the general inventive concept as defined by the appended claims and their equivalents.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A display device comprising:
a housing;
a first heat-producing element inside the housing;
a first heat pipe contacting the housing and located between the housing and the first heat-producing element, a first end of the first heat pipe disposed in the proximity of the first heat-producing element; and
a heat-radiating element connected to a second end of the first heat pipe to absorb heat from the first heat pipe.

2. The electronic device of claim 1, wherein the heat-radiating element is a fan unit.

3. The electronic device of claim 1, wherein the heat-radiating element is a Peltier element.

4. The electronic device of claim 1, wherein the heat-radiating element is a heat sink.

5. The electronic device of claim 2, wherein the fan unit has a case comprising a wall formed of a metal, and the second end of the first heat pipe is connected to the wall to absorb heat from the first heat pipe.

6. The electronic device of claim 5, wherein the wall includes an inlet port to take in air outside the housing.

7. The electronic device of claim 6, further comprising:
a second heat-producing element inside the housing; and
a second heat pipe having a first end which is connected to the second heat-producing element to absorb heat from the second heat-producing element and a second end which is positioned with respect to the fan unit to be cooled by the fan unit.

8. The electronic device of claim 6, further comprising:
a leg positioned in a gap between the second end of the first heat pipe and the fan unit, the leg connecting the second end of the first heat pipe to the wall to absorb heat from the first heat pipe; and
a second heat pipe having a first end which is connected to the second heat-producing element to absorb heat from the second heat-producing element and a second end which is positioned with respect to the fan unit to be cooled by the fan unit.

9. The electronic device of claim 8, wherein the second heat pipe is positioned to substantially overlap with the first heat pipe when viewed from the side.

10. The electronic device of claim 6, wherein the first heat-producing element contacts the first end of the first heat pipe.

11. A display device comprising:
a housing comprising a display panel;
a heat-producing element inside the housing;
a heat pipe contacting the housing between the housing and the heat-producing element, a first end of the heat pipe disposed in the proximity of the heat-producing element; and
a heat-radiating element contacting a second end of the heat pipe to absorb heat from the heat pipe.
